(19) United States
(12) Patent Application Publication
(10) Pub. No.: US 2026/0287676 A1
(43) Pub. Date: Sep. 24, 2026

(54) SYSTEMS AND METHODS FOR DETERMINING WHEN TO TRIGGER AN ABORT PROCESS DURING SEMICONDUCTOR FABRICATION PROCESSING

(71) Applicant: ASM IP Holding B.V., Almere (NL)

(72) Inventors: Yang Wang, Chandler, AZ (US); Shujin Huang, Phoenix, AZ (US); Junwei Su, Chandler, AZ (US); Nathan Casey, Tempe, AZ (US); Srinath Murali, Mesa, AZ (US)

(21) Appl. No.: 19/568,988

(22) Filed: Mar. 17, 2026

Related U.S. Application Data
(60) Provisional application No. 63/775,063, filed on Mar. 20, 2025.

(51) Int. Cl. G01R 31/44; G01R 21/02; G01R 27/08; H05B 3/00; H10P 72/00

(52) U.S. Cl. CPC G01R 31/44; G01R 21/02; G01R 27/08; H05B 3/0047; H10P 72/0602; H10P 72/0604; H05B 2203/007

(57) ABSTRACT

Methods and systems for determining when to trigger an abort process during semiconductor manufacturing processing are disclosed. An exemplary method includes measuring a plurality of resistances of the heat lamp during a time period, performing N consecutive comparisons of a prior resistance of the measured plurality of resistances to a current resistance of the measured plurality of resistances, to determine whether a difference between each comparison of the prior resistance and the current resistance exceeds a threshold, triggering the abort process based on the difference between each of the N consecutive comparisons of the prior resistance and the current resistance exceeding the threshold, and generating one or more instructions to suspend the semiconductor fabrication process based on triggering the abort process. An exemplary system can perform the method of determining when to trigger an abort process.

### CROSS-REFERENCE TO RELATED APPLICATIONS

This application is a nonprovisional of, and claims priority to and the benefit of, U.S. Provisional Patent Application No. 63/775,063, filed Mar. 20, 2025 and entitled “SYSTEMS AND METHODS FOR DETERMINING WHEN TO TRIGGER AN ABORT PROCESS DURING SEMICONDUCTOR FABRICATION PROCESSING,” which is hereby incorporated by reference herein.

### FIELD

The disclosure generally relates to systems that include lamps used in semiconductor fabrication processing and to methods of using such systems. More specifically, the disclosure relates to systems and methods for determining when to trigger an abort process during semiconductor fabrication processing.

### BACKGROUND OF THE DISCLOSURE

The use of one or more lamps in semiconductor fabrication processing is known and in an example, such lamps may be positioned adjacent and external to a reaction chamber used for semiconductor fabrication. Such lamps can be used to provide heat in the form of infrared (IR) energy into a chamber of the reactor containing a substrate during one or more stages of the semiconductor fabrication process to, for example, maintain a desired deposition temperature therein when a precursor is introduced in the reaction chamber and across the substrate. As such lamps are reused over and over again in subsequent semiconductor fabrication processes, the efficiency or service life of the lamps degrade and/or the lamps fail over time and need to be replaced.

It is known to replace such lamps after the passage of a predetermined amount of time has passed, e.g., a predetermined amount of time after the lamp when new was installed, or after a lamp failure. However, this approach of cyclic lamp replacement based on such predetermined time or lamp failure may lead to prolonged use of lamps that are no longer effective or reliable and/or may result in the unnecessary replacement of lamps that are still efficient and reliable. This occurs because each lamp can have an individualized power ratio applied to it, such that some lamps in the system may have more power applied to them over the same amount of time.

Further, if the lamp health gets to a point where it no longer functions properly, using that lamp during semiconductor fabrication processing may lead to poor results with respect to the quality of the substrate. Additionally, use of a degraded lamp may lead to discarding the substrate and restarting the semiconductor fabrication process, leading to low throughput with respect to the semiconductor fabrication process.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

Accordingly, it is desired to have a system and method for determining when to trigger an abort process during a semiconductor manufacturing process, based on monitoring a condition of one or more lamps. In doing so, lamps may be replaced in order to avoid the extended use of inefficient or unreliable lamps. Further, the semiconductor fabrication process may be suspended based on determining that the condition of a lamp has degraded to a point at which the lamp may need to be replaced.

Example systems as disclosed herein are configured to determine when to trigger an abort process during semiconductor fabrication processing. In an example, semiconductor fabrication processing makes use of a reactor comprising a reaction chamber. A substrate support or susceptor is disposed within the reaction chamber, and a lamp is disposed outside of the reaction chamber and optically coupled to the susceptor via a wall of the chamber. In an example, the lamp may be any lamp used in the semiconductor fabrication process. In an example, the lamp is a heat lamp that provides radiant energy or heat inside of the chamber. Further, systems and methods described herein may suitably use a plurality of such lamps about an exterior of the reaction chamber.

An exemplary system comprises a controller that is configured or programmed to determine when to trigger an abort process during a semiconductor fabrication process. In an example, the controller is configured or programmed to measure a plurality of resistances of a heat lamp during a time period. In an example, the controller is configured or programmed to compare a first resistance of the measured plurality of resistances to a second resistance of the measured plurality of resistances to determine whether a difference between the first resistance and the second resistance exceeds a threshold, in which the first resistance is measured prior to the second resistance. In an example, the controller is configured or programmed to compare the second resistance to a third resistance of the measured plurality of resistances to determine whether a difference between the second resistance and the third resistance exceeds the threshold, in which the second resistance is measured prior to the third resistance. In an example, the controller is configured or programmed to trigger the abort process based on the difference between the first resistance and the second resistance exceeding the threshold, and the difference between the second resistance and the third resistance exceeding the threshold. In an example, the controller is configured or programmed to generate one or more instructions to suspend the semiconductor process, based on triggering the abort process.

In an example, the threshold may be between 0.5 Ohms and 2 Ohms. In an example, the measuring the plurality of resistances is performed after an etching process and before a pre-coating process of the semiconductor fabrication process.

In an example, the controller is further configured or programmed to control a user interface, based on the abort process being triggered, to display an indication that the abort process was triggered.

In an example, the exemplary system further includes a plurality of heat lamps disposed outside of the reaction chamber and optically coupled to the susceptor by the wall of the reaction chamber. In an example, the controller is further programmed or configured to determine when to trigger the abort process for each heat lamp of the plurality of heat lamps.

In an example, the exemplary system further includes a sensor that determines an electrical current of the heat lamp, in which the controller measures the plurality of resistances from the electrical current of the heat lamp as determined by the sensor and an amount of electrical power used to power the heat lamp.

In an example, each of the plurality of resistances is measured by using the mathematical equation P=I²R. In an example, the amount of electrical power is determined using one or more pyrometers.

In an example, the system comprises a controller configured or programmed to measure a plurality of resistances of the heat lamp during a time period. In an example, the controller is configured or programmed to perform N consecutive comparisons of a prior resistance of the measured plurality of resistances to a current resistance of the measured plurality of resistances, to determine whether a difference between each comparison of the prior resistance and the current resistance exceeds a threshold. In an example, the controller is configured or programmed to trigger the abort process based on the difference between each of the N consecutive comparisons of the prior resistance and the current resistance exceeding the threshold. In an example, the controller is configured or programmed to generate one or more instructions to suspend the semiconductor fabrication process based on triggering the abort process.

In an example, the system comprises a controller that comprises one or more processors, and memory storing computer-executable instructions, that when executed by the one or more processors, cause the controller to determine when to trigger an abort process during a semiconductor manufacturing process, in accordance with aspects described herein.

In an example, the system comprises a controller that comprises one or more computer-readable media, that when executed by the controller, cause the controller to determine when to trigger an abort process during a semiconductor manufacturing process, in accordance with aspects described herein.

In an example, a method of determining when to trigger an abort process during a semiconductor process is performed by measuring a plurality of resistances of a heat lamp during a time period, comparing a first resistance of the measured plurality of resistances to a second resistance of the measured plurality of resistances to determine whether a difference between the first resistance and the second resistance exceeds a threshold, in which the first resistance is measured prior to the second resistance, comparing the second resistance to a third resistance of the measured plurality of resistances to determine whether a difference between the second resistance and the third resistance exceeds the threshold, in which the second resistance is measured prior to the third resistance, triggering the abort process based on the difference between the first resistance and the second resistance exceeding the threshold, and the difference between the second resistance and the third resistance exceeding the threshold, and generating one or more instructions to suspend the semiconductor process, based on triggering the abort process.

In an example, a method of determining when to trigger an abort process during a semiconductor process is performed by measuring a plurality of resistances of the heat lamp during a time period, performing N consecutive comparisons of a prior resistance of the measured plurality of resistances to a current resistance of the measured plurality of resistances, to determine whether a difference between each comparison of the prior resistance and the current resistance exceeds a threshold, triggering the abort process based on the difference between each of the N consecutive comparisons of the prior resistance and the current resistance exceeding the threshold, generating one or more instructions to suspend the semiconductor fabrication process based on triggering the abort process.

Such example systems and methods disclosed herein enable independent monitoring of a condition of one or more heat lamps during use in semiconductor fabrication processes, to provide a more reliable approach to determine when to suspend a semiconductor fabrication process, in order to replace degraded heat lamps that have been determined to be approaching the end of their determined effective service life.

### BRIEF DESCRIPTION OF THE DRAWINGS

A more complete understanding of exemplary embodiments of the present disclosure can be derived by referring to the detailed description and claims when considered in connection with the following illustrative figures.

FIG. 1 is a schematic diagram of a heat lamp system in accordance with exemplary embodiments of the disclosure;

FIG. 2 is a cross-sectional view of a reactor system in accordance with additional exemplary embodiments of the disclosure;

FIG. 3 is a cross-sectional view of a reactor system in accordance with additional exemplary embodiments of the disclosure;

FIG. 4 is a cross-sectional top view of a reactor system in accordance with additional exemplary embodiments of the disclosure;

FIG. 5 is a schematic diagram of a heat lamp system in accordance with additional exemplary embodiments of the disclosure;

FIG. 6 is a diagram of a method of determining when to trigger an abort process in accordance with exemplary embodiments of the disclosure;

FIG. 7 is a diagram of a method of determining when to trigger an abort process in accordance with exemplary embodiments of the disclosure; and

FIG. 8 illustrates a user interface in accordance with exemplary embodiments of the disclosure.

### DETAILED DESCRIPTION

Reference will now be made to the drawings wherein like reference numerals identify similar structural features or aspects of the subject disclosure. While in this description the systems or methods disclosed herein may be described for use with heat lamps used during semiconductor fabrication processing, it is to be understood that systems and methods disclosed herein for determining when to trigger an abort process may be used with heat lamps or any other types of lamps that may be used in the semiconductor fabrication process.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or other derived representative value. Further, in this disclosure, the terms “include,” “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

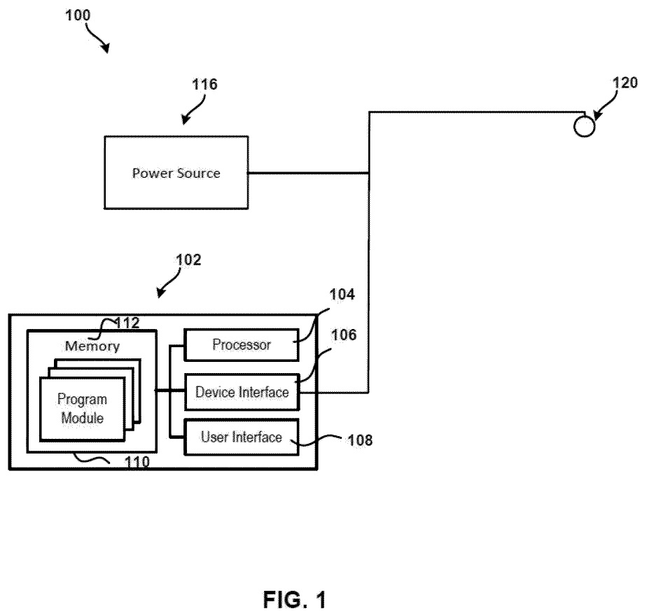

FIG. 1 illustrates an exemplary heat lamp system 100 suitable for use in a reactor system. Heat lamp system 100 includes a heat lamp 120 and a controller 102. Heat lamp 120 can include any suitable heat lamp, for example, an infrared heating lamp. Heat lamp 120 may be a linear lamp. Heat lamp 120 may be a spot-type lamp. The heat lamp system 100 may include linear lamps, spot lamps, or both linear lamps and spot lamps. Controller 102 can be configured to provide independent control to the heat lamp 120. An electrical power source 116 can be in electronic communication with the heat lamp 120, and the electrical power source 116 is configured to send power to the heat lamp 120. The electrical power source 116 is also in electronic communication with the controller 102. By way of example, controller 102 can be configured to generate signals (e.g., power ratio output) for independently controlling heat lamp 120 based on sensed temperatures. Exemplary methods of generating the control signals are described below.

In the illustrated example, controller 102 includes a processor 104 that manages memory 112 of the controller 102 (or accessible by controller 102), and program module 110 that can include software or executable instructions or code that may be executed by processor 104 to provide temperature monitoring and control functions described herein. Controller 102 can further include a user interface 108 for facilitating an operator selecting between control or program module 110, interacting with monitored temperature data, modifying, or updating deposition or processing parameters, and the like. User interface 108 can include a graphical user interface (GUI) generated by the processor 104 that may be displayed on a monitor, touchscreen, or the like. The GUI can be used to, for example, display an indication that an abort process was triggered, as described herein. A device interface 106 (including, e.g., data registers, a data bus, data lines, address lines, or the like) may be provided as part of controller 102 with one or more input/output (I/O) components to facilitate wired or wireless communications between controller 102 and heat lamp 120.

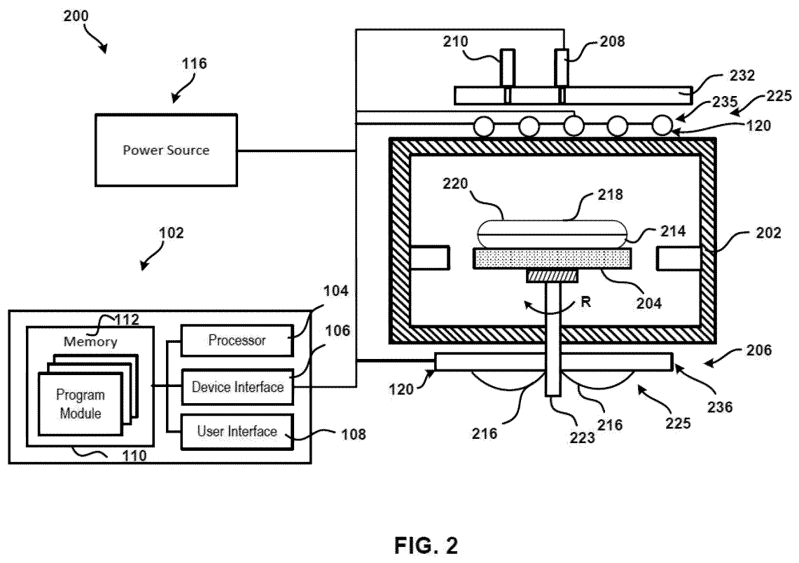

FIG. 2 illustrates an exemplary reactor system 200 suitable for chemical vapor deposition (CVD) as used with semiconductor fabrication. Reactor system 200 includes a reaction chamber 202, a substrate support or susceptor 204 configured to seat a substrate 214, a heat lamp array 225 with one or more heat lamps 120, a first pyrometer 208, a second pyrometer 210, and the controller 102. Reactor system 200 can also include a reflector or reflective surface 232, wherein at least a portion of heat lamp array 225 is between reflective surface 232 and reaction chamber 202. The reactor system 200 can be an epitaxial reactor system which utilizes atmospheric pressure (e.g., between about 500 torr and about 760 torr) or reduced pressure (e.g., between about 3 torr and about 500 torr) during deposition. The controller 102 can be as described above and can be configured to individually control the power ratio output from the electrical power source 116 to each heat lamp 120 of the heat lamp array 225.

As discussed in more detail below, heat lamp array 225 can include one or more heat lamps aligned in a first direction and one or more heat lamps aligned in a second (e.g., substantially perpendicular—e.g., 85-95 degrees offset from the first direction) direction. For example, heat lamp array 225 can include a first portion of heat lamps 235 aligned in a first direction and a second portion of heat lamps 236 aligned in a second direction. The heat lamps 120 can be or include linear lamps. In addition, heat lamp array 225 can include one or more (e.g., infrared) spot lamps 216. The heat lamp array 225 is supported outside the reaction chamber 202 to provide heat energy in the reaction chamber 202 without appreciable absorption by reaction chamber walls.

In an example, the reactor system 200 is used for performing epitaxial deposition of material comprising silicon on a single substrate. In an example, the reactor system 200 is capable of accomplishing multiple deposition steps in the reaction chamber 202. While the reaction chamber 202 has been described for use in depositing material comprising silicon, it is to be understood that the reaction chamber 202 may be used to deposit other materials other than silicon during the semiconductor fabrication process. Also, while the exemplary embodiments are described in the context of a chemical vapor deposition or epitaxial reactor for processing semiconductor wafers, the processing methods described herein have utility in conjunction with other heating and/or cooling systems, such as those employing inductive or resistive heating.

Reaction chamber 202 can be formed of any suitable material, such as ceramic materials including quartz and sapphire, or any other material transparent to radiation emitted from lamps 120, 216. By way of particular example, reaction chamber 202 can be formed of quartz, which transmits electromagnetic radiation emitted by lamps 120, 216, as well as radiation emitted by a substrate supported on the substrate support 204 to the pyrometers 208, 210, and from which the pyrometers 208, 210 determine temperature at, for example, a substrate first location 218 and a substrate second location 220 corresponding to the spacing of the pyrometers 208, 210. In certain examples, the reaction chamber 202 may have planar walls, such as a planar upper wall and a planar lower wall. In accordance with certain examples, one or more of the upper wall and the lower wall may have an arcuate or dome-like shape.

Substrate support 204 can be formed of for example, graphite, and may have silicon carbide coating. In some cases, substrate support 204 is formed of material that emits radiation used by pyrometers 208, 210 to measure a temperature of substrate support 204. As illustrated, substrate support 204 can be connected to a rotatable shaft 223 that is configured to cause substrate support 204 to rotate in a direction R.

While FIG. 2 illustrates a single reactor (e.g., a single-wafer, cold-wall, cross-flow reactor) used for semiconductor device fabrication, it is understood that semiconductor fabrication processes may make use of equipment comprising two or more such reactors that are operated to facilitate scaling the fabrication of multiple semiconductors. Accordingly, systems and methods as disclosed herein may be configured to monitor the lamps of a single reactor or the lamps of multiple reactors according to the specific type of semiconductor fabrication equipment being used.

In an example embodiment, the heat lamps 120 are powered by a power source 116 that is independent of powering other elements used during the semiconductor fabrication process and that provides a known amount or level of electrical power, such that each individual heat lamp independently receives a known amount of electrical power. In an example, the heat lamps may each be powered by a respective separate electrical power source or may each be powered by the same electrical power source 116. Whether powered by a same electrical power source 116 or multiple electrical power sources 116, each lamp 120, 216 can receive individualized power based on, for example, direct heat distribution within the reaction chamber or across a substrate. The individualized or independent power can be based on a ratio of total power output of the one or more power sources.

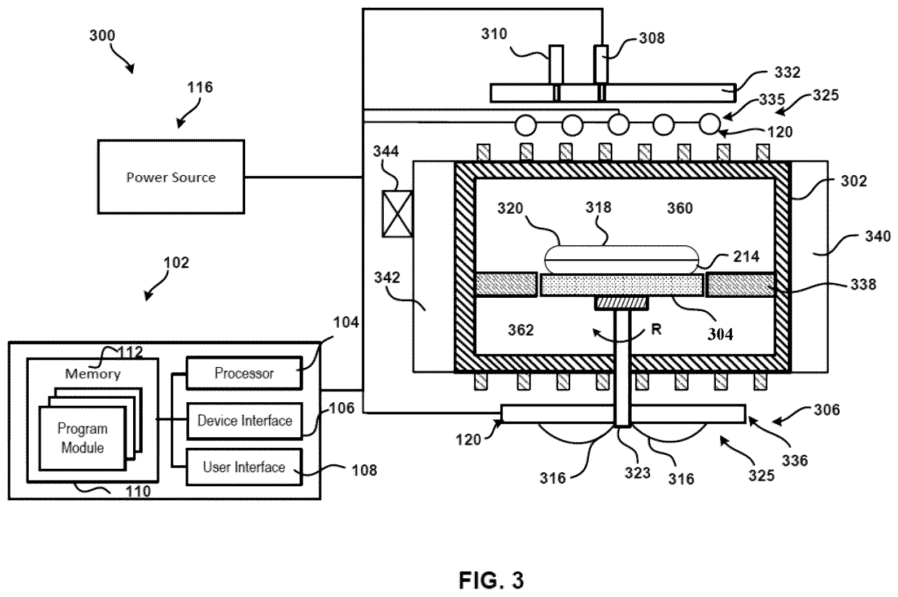

FIG. 3 illustrates another exemplary reactor system 300 suitable for semiconductor fabrication. Reactor system 300 includes a reaction chamber 302, a substrate support or susceptor 304, a heat lamp array 335 with one or more heat lamps 120, a first pyrometer 308, a second pyrometer 310, and the controller 102. Reactor system 300 can also include a reflector or reflective surface 332, wherein at least a portion of heat lamp array 325 is between reflective surface 332 and reaction chamber 302. The reactor system 300 can be, for example, an epitaxial reactor system, which utilizes reduced pressure, for example the pressure in the reaction chamber 302 can be between about 3 torr and about 500 torr during operation. The controller 102 can be as described above and can independently control the power ratio output from the one or more electrical power source(s) 116 to each heat lamp 120 of the heat lamp array 325.

The reactor system 300 also includes a divider 338 disposed within the reaction chamber 302. The divider 338 is used to help separate the top section 360 and bottom section 362 of the reaction chamber 302. An injection flange 342 is disposed at one end of the reactor system 300 and is constructed and arranged to introduce precursors and/or reactants into the reaction chamber 302. A gate valve 344 can be disposed at the same end and can be used to open and close to allow loading and unloading of substrates. An exhaust flange 340 is disposed on the opposite end of the reactor system 300 and the exhaust flange 340 is constructed and arranged to remove exhaust gases from the reaction chamber 302 during or after deposition.

As discussed in more detail below, heat lamp array 325 can include one or more heat lamps aligned in a first direction and one or more heat lamps aligned in a second (e.g., substantially perpendicular—e.g., 85-95 degrees offset from the first direction) direction. For example, heat lamp array 325 can include a first portion of heat lamp array 335 aligned in a first direction and a second portion of heat lamps 336 aligned in a second direction. The heat lamps 120 can be or include linear lamps. In addition, heat lamp array 325 can include one or more (e.g., infrared) spot lamps 316. The heat lamp array 325 is supported outside the reaction chamber 302 to provide heat energy in the reaction chamber 302 without appreciable absorption by reaction chamber walls.

In an example, the reactor system 300 is used for performing epitaxial deposition of material comprising silicon on a single substrate. In an example, the reactor system 300 is capable of accomplishing multiple deposition steps in the reaction chamber 302. Additionally, or alternatively, reaction chamber 302 may be used to deposit materials other than silicon, and/or etch a surface, and/or clean a surface during the semiconductor fabrication process. The processing methods described herein can also have utility in conjunction with other heating and/or cooling systems, such as those employing inductive or resistive heating.

Reaction chamber 302 can be formed of any suitable material, such as ceramic materials including quartz and sapphire, or any other material transparent to radiation emitted from lamps 120, 316. By way of particular example, reaction chamber 302 can be formed of quartz, which transmits electromagnetic radiation emitted by lamps 120, 316, as well as radiation emitted by a substrate supported on the substrate support 304 to the pyrometers 308, 310, and from which the pyrometers 308, 310 determine temperature at, for example, a substrate first location 318 and a substrate second location 320 corresponding to the spacing of the pyrometers 308, 310. Other reactor system 300 components 102, 116, 120, and 214 can be as described above in connection with FIG. 2.

While FIG. 3 illustrates a single reactor used for semiconductor fabrication, it is understood that semiconductor fabrication processes may make use of equipment comprising two or more such reactors that are operated to facilitate scaling the fabrication of multiple semiconductors. Accordingly, systems and methods as disclosed herein may be configured to monitor the lamps of a single reactor or the lamps of multiple reactors according to the specific type of semiconductor fabrication equipment being used.

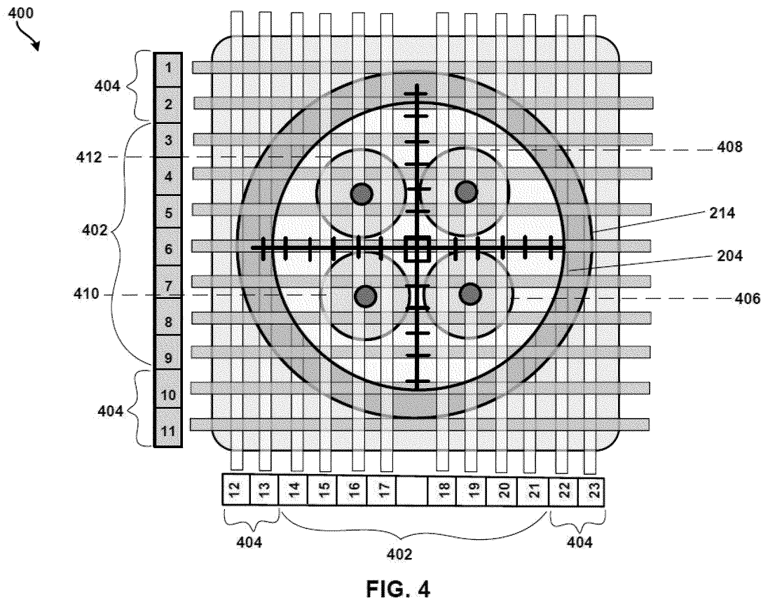

FIG. 4 illustrates an exemplary heat lamp array 400 suitable for use as heat lamp arrays 225 and 325 in accordance with examples of the disclosure. Heat lamp array 400 includes a first zone of one or more heat lamps 402 and a second zone of one or more heat lamps 404. Exemplary heat lamp arrays can suitably include more than two zones of heat lamps. For example, exemplary heat lamp arrays can include 3, 4, 5, 7, or more zones. Although illustrated with a particular number of heat lamps in first zone of heat lamps 402 and second zone of heat lamps 404, any suitable number of heat lamps can be used in respective zones. Further, the first zone of one or more heat lamps 402 and a second zone of one or more heat lamps 404 can comprise the heat lamps described as heat lamps 120 disclosed herein.

By way of examples, first zone of heat lamps 402 can include one or more linear heat lamps above and/or below substrate support 204 (FIG. 2), substrate support 304 (FIG. 3) or above and/or below reaction chamber 202 (FIG. 2), reaction chamber 302 (FIG. 3). The linear heat lamps can be, for example, silicon-controlled rectifier (SCR) linear lamps. Each linear lamp can exhibit, for example, about 10,000 W maximum output. Additionally or alternatively, second zone of heat lamps 404 can include one or more linear lamps above and/or below substrate support 204, substrate support 304 or above and/or below reaction chamber 202, reaction chamber 302. In addition, one or more of the first zone of heat lamps 402 or the second zone of heat lamps 404 can include one or more spot lamps 406-412 above and/or below substrate support 204, substrate support 304, or reaction chamber 202, reaction chamber 302. The spot lamps can each be formed of, for example, four individual round spots and can be located, for example, below substrate support 204 and reaction chamber 202 (FIG. 2), or below substrate support 304 and reaction chamber 302 (FIG. 3). The maximum capacity of each (e.g., round) spot lamp can be about 1000-2000 W.

In the illustrated example shown in FIG. 4, heat lamp array 400 includes heat lamps 1-11 above substrate support 204 (FIG. 2) and substrate support 304 (FIG. 3) or reaction chamber 202 (FIG. 2) and reaction chamber 302 (FIG. 3), and heat lamps 12-23 and spot lamps 406-412 below substrate support 204 and substrate support 304 or reaction chamber 202 and reaction chamber 302. Various configurations and numbers of heat lamps are contemplated, and the heat lamps can comprise linear heat lamps. For example, first zone of one or more heat lamps 402 can include 2 to 12 or 2 to 8 or 2 to 4 (e.g., linear) first zone heat lamps above and/or below substrate support 204 and substrate support 304 or reaction chambers 202 and 302 (for a total of 2 to 24 or 2 to 16 or 2 to 8 linear heat lamps). Additionally, or alternatively, second zone of one or more heat lamps 404 can include 2 to 12 or 2 to 8 or 2 to 4 (e.g., linear) second zone heat lamps—above or below substrate support 204 and substrate support 304 and/or reaction chamber 202 and reaction chamber 302 (for a total of 2 to 24 or 2 to 16 or 2 to 8 heat lamps). Further, one or more of the first zone of heat lamps 402 and second zone of heat lamps 404 can optionally be 1 to 10 or 2 to 6or about 4 spot lamps above and/or below substrate support 204 and substrate support 304 or reaction chamber 202 and reaction chamber 302. The specific example illustrated in FIG. 4 includes first zone of one or more heat lamps 402 including 7 first zone heat lamps (heat lamps 3-9) above reaction chambers 202 and 302, 8 first zone heat lamps (heat lamps 14-21) below reaction chambers 202 and 302 and four first zone spot lamps 406-412 below reaction chambers 202 and 302. Second zone of one or more heat lamps 404 includes four (e.g., linear) second zone heat lamps (heat lamps 1, 2, 10, and 11) above reaction chambers 202 and 302 and four (e.g., linear) second zone heat lamps (heat lamps 12, 13, 22, and 23) below reaction chambers 202 and 302.

In accordance with examples of the disclosure, heat lamps (e.g., heat lamps 3-9 and 14-21) of first zone of heat lamps 402 are located inward of heat lamps (e.g., heat lamps 1, 2, 10,-13 , 22, and 23) of second zone of heat lamps 404. Other configurations are also contemplated. For example, heat lamps of second zone of heat lamps 404 can be located inward of heat lamps of first zone of heat lamps 402. Alternatively, heat lamps of first zone of heat lamps 402 can alternate or be grouped in other configurations.

Referring again to FIGS. 2 and 3, controller 102 can be configured to provide independent control to one or more of the zones of heat lamps (e.g., zones of heat lamps 402 and 404) and/or one or more heat lamps within each zone of heat lamps (e.g., heat lamps 1-23). A power offset can be used to provide different power levels to various heat lamps within a zone of heat lamps to obtain a desired temperature profile and/or to account for varying efficiencies of one or more heat lamps within the zone of heat lamps.

By way of example, controller 102 can be configured to generate signals (e.g., proportional power outputs) for independently controlling first zone of heat lamps 402 based on sensed temperatures at a first substrate or susceptor location 218 (FIGS. 2) and 318 (FIG. 3) and for independently controlling second zone of heat lamps 404 based on sensed temperatures at a second substrate or susceptor location 220 and 320. To this end, the temperature information or pyrometer temperature outputs, are communicated to controller 102 for processing and, in response, controller 102 generates (e.g., corresponding power ratio) outputs to heat lamps 1-23 or to zones of heat lamps 402 and 404. These (e.g., power ratio) outputs from controller 102 can be assigned individually to each heat lamp or to each heat lamp within a zone depending on the desired control profile determined by the sensed temperatures within the reaction system.

Although all the heat lamps may be operated for the same amount of time and accrue the same total operating hours, certain heat lamps may age faster than others due to, for example, a power ratio output assigned to each heat lamp for processes occurring in the reaction chamber. Monitoring the heat lamps individually allows for identification of faster aging heat lamps, thus facilitating heat lamp replacements and/or heat lamp position swaps, such as moving a heat lamp from a high-power ratio output position to a low power ratio output position once the monitoring data shows that the heat lamp is beginning to fail. This allows one to avoid a time-based total lamp array replacement strategy, and instead replace or reposition lamps when the controller 102 triggers an abort process, as discussed in more detail below.

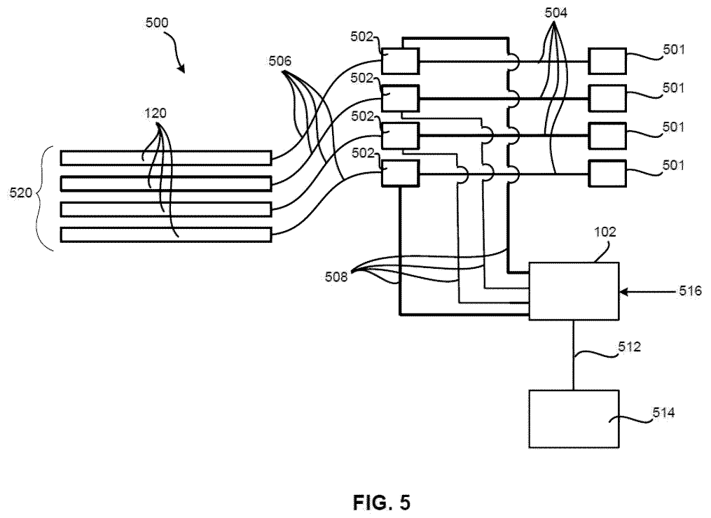

FIG. 5 is a diagram illustrating another system 500. System 500 includes a number of heat lamps 120 in a heat lamp array 520 used in the semiconductor fabrication process and disposed in a reactor system. The heat lamp array 520 can be used as heat lamp arrays 225, 325, and/or 400. In an example embodiment, the heat lamps 120 receive electrical power from an electrical power source 116 as described above. In the example illustrated, each heat lamp 120 receives electrical power from a respective separate electrical power source 501 which can form part of power source 116. Each power source 501 can be configured to provide a ratio of power to individual heat lamps 120 and/or to zones of heat lamps 120. In an example, sensor(s) 502 may be interposed between each heat lamp 120 and a respective electrical power source 501, and each sensor 502 (e.g., power sensor, current sensor, or the like) is configured to receive electrical power from a respective electrical power source 501 by a suitable electrical conductor, wire, or cable 504. The electrical power received by each sensor 502 is passed to a respective heat lamp 120 by a suitable electrical conductor, wire, or cable 506. Alternatively, the sensors 502 may be configured to connect directly to a conductive terminal of the heat lamp, thereby avoiding the use of wires or cables. In an example, the sensors 502 are configured to transfer or pass through the electrical power received from the electrical power source to the heat lamps without changing the amount of electrical power. In an example, the sensors are configured to measure the amount of electrical current or current flow associated with a respective heat lamp.

In an example, the heat lamp is a direct current (DC) device and the electrical power source or power sources 501 are configured to provide DC power to each heat lamp 120. In such example, each power source 501 may be provided in the form of rectifiers such as silicon-controlled rectifiers (SCR) or the like. In an example, the electrical current flow of each heat lamp 120 as determined by a respective sensor 502 (which may form part of an SCR) is transferred by suitable electrical conductor, wire, or cable 508 to a controller (such as controller 102). Alternatively, the current information as measured by each sensor 502 may be transferred from each sensor 502 to the controller 102 wirelessly through the use of wireless transmitters and receivers. The power provided and measured can be used to obtain a resistance value for each heat lamp which can be recorded and stored in the controller 102.

As briefly noted above, with reference to FIGS. 1-5, systems, and methods for determining when to trigger an abort process as disclosed herein comprise the controller 102 that makes use of heat lamp data or information storage or memory, and a program for determining and/or comparing heat lamp resistances. With reference to FIG. 5, in an example, the controller 102 is configured to provide an indication of the state or condition of the individual heat lamps. The indication may be customized or differently provided depending on user preference or the like. In an example, the controller 102 may be connected by wire 512 or wirelessly to a device 514 for the purpose of displaying, e.g., providing a visual indication of, the status or condition of the heat lamps, and/or for providing an indication of when an abort process was triggered by the controller 102, for purposes of thereafter taking action to replace the heat lamp. Also, it is to be understood that the device 514 useful for providing an indication of the heat lamp condition or state may be located near or remote from the semiconductor fabrication process machinery depending on the particular user preference or situation.

As noted above, in an example the system comprises storage or memory that contains all of the determined heat lamp resistance values for the individual heat lamps. In an example, each determined heat lamp resistance value includes a date and time for condition monitoring or tracking purposes. Additionally, the system may be configured to enable user input 516 for storing certain heat lamp information such as, information about the type of each individual heat lamp, information about the date and time that a new heat lamp was installed, and information about the placement position of the lamp relative to the reactor. These are but a few examples of different types of information that may be input into the system as it relates to the heat lamps, and it is to be understood that other types of information that may be useful for tracking and monitoring heat lamp health may also be included and all such other information is intended to be within the scope of determining when to trigger an abort process during semiconductor fabrication processing as disclosed herein.

In an example, the system 500 may be configured to provide a desired user interface as viewable on a device, such as a device 514, which may be customized depending on desired user preferences or the like. In an example, the system 500 may provide a display menu enabling the user to select different display formats or pages such as graphic display, chart display, or the like showing the determined resistance value or effective service life history of each individual lamp, or the most recently determined resistance value or effective service life of the individual lamps. These are but a few examples of heat lamp health display formats that may be provided in accordance with the system, and it is to be understood that display formats other than those specifically disclosed are intended to be within the scope of determining when to trigger an abort process as disclosed herein. In an example, the device may be in the form of a touchscreen display or the like to thereby facilitate user input or interaction with the heat lamp information menu.

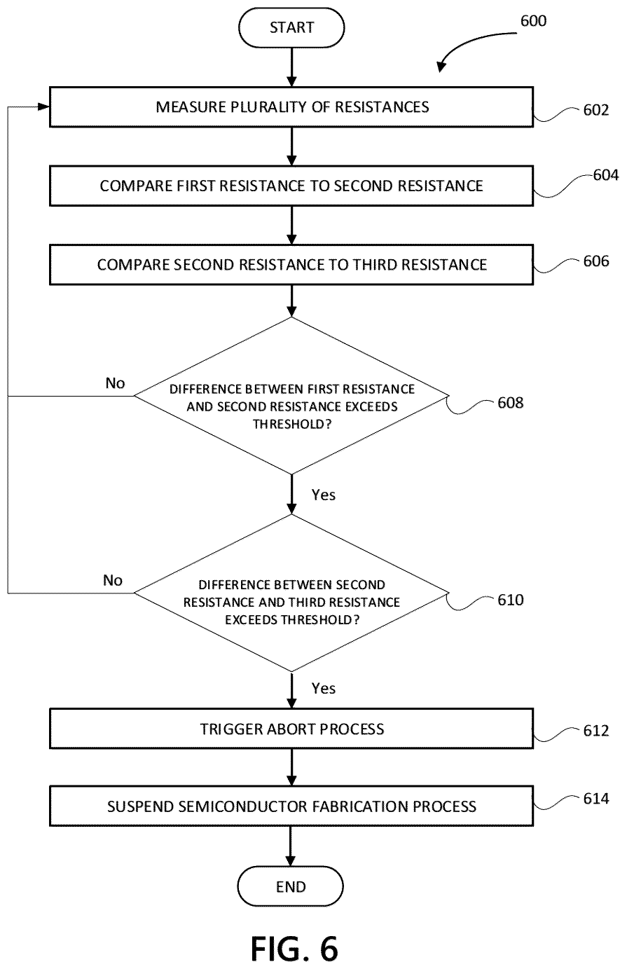

FIG. 6 illustrates an exemplary method 600 for determining when to trigger an abort process according to one or more aspects of the present disclosure. FIGS. 1-5 illustrate heat lamp systems and reactor systems suitable for use in conjunction with method 600. Method 600 can be used on both reduced pressure and atmospheric epitaxial reaction chambers, such as those reaction chambers disclosed herein. One or more of the steps shown in FIG. 6 may be rearranged, omitted, and/or otherwise modified, and/or other steps added without departing from the scope of the disclosure.

Method 600 may begin with step 602, which involves measuring a plurality of resistances of a heat lamp within a reactor system, such as reactor systems 200 or 300. In an example, the controller 102 is configured and/or programmed to include or measure the known amount of electrical power that is directed to each heat lamp and to determine, from the known amount of electrical power and the measured electrical current flow of the heat lamp (provided by each sensor), a resistance of each individual heat lamp 120. In an example, the controller 102 is programmed to determine the resistance of each individual heat lamp by using the mathematical equation P=I²R, where “P” equals the electrical power (Watts), “I” equals the electrical current (Amps), and “R” is the resistance (Ohms). The power can be the power provided to a heat lamp to obtain a desired temperature as measured and controlled using one or more pyrometers, 208, 210, 308, and 310. Configured in this manner, the controller 102 is programmed to determine the resistance associated with each individual heat lamp. In an example, resistance values may be stored in a memory 112 of the controller 102 or otherwise logged. In an example, the controller 102 can base the measured resistances off of either a reduced pressure baseline power or an atmosphere pressure baseline power based on which reactor system is being used.

The resistances may be measured at the beginning or end of each process and/or may be measured at periodic intervals and/or before and/or after a semiconductor fabrication process. In an example, for purposes of determining resistance values of each heat lamp at a known or consistent operating or heating state during the semiconductor fabrication process (i.e., for purposes of consistency), the controller 102 is programmed by a user or the like to determine the heat lamp resistance at the same or similar determined operating or heating state during each subsequent semiconductor fabrication process. The particular state of operation that is determined for such heat lamp resistance determination may vary depending on a number of factors such as the user's preferences associated with the semiconductor fabrication process (e.g., preferences associated with a throughput of one of more substrates, or the like), the particular type of semiconductor fabrication process and the different operating states of the same, and/or the type(s) of heat lamps or other lamps to be measured that are used.

It can be advantageous to measure the plurality of resistances when the reactor is not too busy, such as during a cleaning or etching of the reactor, e.g., after a deposition process. In an example, depending on the particular names given to the different operating cycles, the desired consistent operating cycle for heat lamp resistance determination may be during what may be referred to as a “pre-idle recipe.” While the particular operating cycle selected for determining heat lamp resistance may vary, it is to be understood that a feature of such cycle that is selected is that it is the same for each subsequent heat lamp resistance determination for purposes of providing a consistent heat lamp use condition each time so that each subsequent heat lamp resistance determination occurs under the same use conditions.

During step 602, a constant predetermined power can be supplied to each lamp. An average, mean or median resistance for each lamp can be measured and calculated e.g., using sensors such as sensors 502. In an example, the plurality of resistances are measured after an etching process and before a pre-coating process of the semiconductor fabrication process.

At step 604, the controller 102 may compare a first resistance of the heat lamp to a second resistance of the heat lamp. In an example, the first resistance is measured prior to the second resistance.

At step 606, the controller 102 may compare the second resistance of the heat lamp to a third resistance of the heat lamp. In an example, the second resistance is measured prior to the third resistance.

At step 608, the controller 102 may determine whether a difference between the first resistance and the second resistance exceeds a threshold. If the difference exceeds the threshold, then the method 600 may proceed to step 610. If the difference does not exceed the threshold, then the method 600 may proceed back to step 602.

In an example, the threshold is determined and entered, stored, or otherwise logged for controller access (e.g., entered via user interface 108 and stored within memory 112). The threshold may vary depending on such factors as the particular type of heat lamp that is being used and/or the particular location of the heat lamp relative to the reactor. In an example, the threshold may be configured based on user preferences, depending on how conservative or aggressive the user wishes to be with respect to determining when to trigger the abort process. A user may wish to be more conservative with respect to triggering the abort process in order to err on the side of replacing the heat lamp sooner, as opposed to being more aggressive with respect to triggering the abort process, in order to err on the side of maximizing the lifespan/use of the heat lamp. In an example, the threshold is 0.5 Ohms, representing a more conservative threshold. In another example, the threshold is 2 Ohms, representing a more aggressive threshold. In another example, the threshold is between 0.5 Ohms and 2 Ohms. Different thresholds (e.g., a threshold between 0.5 Ohms and 1.5 Ohms, a threshold between 0.5 Ohms and 1 Ohm, etc.) may be configured without departing from the scope of the disclosure.

At step 610, the controller 102 may determine whether a difference between the second resistance and the third resistance exceeds the threshold. If the difference exceeds the threshold, then the method 600 may proceed to step 612. If the difference does not exceed the threshold, then the method 600 may proceed back to step 602.

At step 612, the controller 102 may trigger the abort process based on the determinations made at step 608 and step 610. This may indicate, for example, that the heat lamp has approached an inefficient operating state that is near or nearing an end of effective service life of the heat lamp.

At step 614, the controller 102 may suspend the semiconductor fabrication process by generating one or more instructions stored at, for example, memory 112, and executed by processor 104. In this manner, the controller 102 may, advantageously, prevent the continuation of the semiconductor fabrication process using a potentially defective heat lamp, which may cause poor quality associated with the production of the substrate.

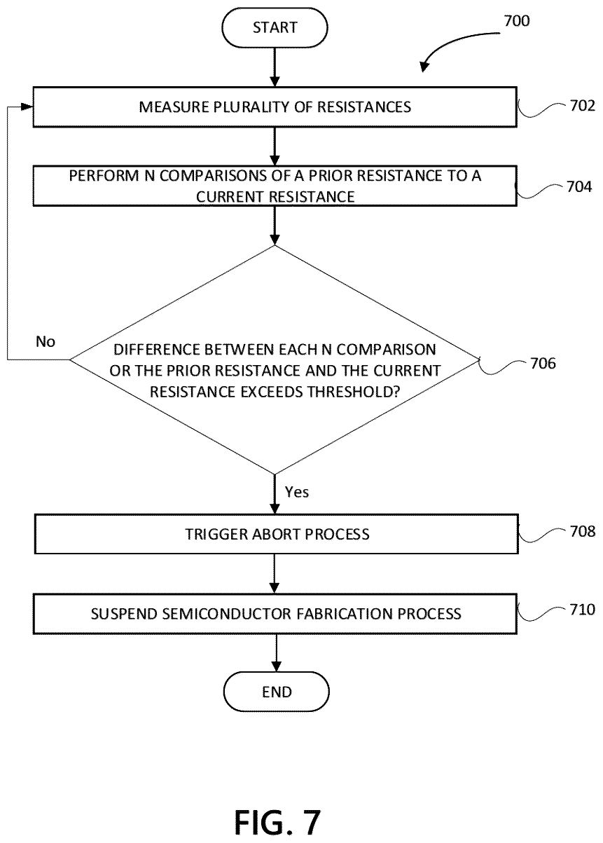

FIG. 7 illustrates an exemplary method 700 for determining when to trigger an abort process according to one or more aspects of the present disclosure. FIGS. 1-5 illustrate heat lamp systems and reactor systems suitable for use in conjunction with method 700. Method 700 can be used on both reduced pressure and atmospheric epitaxial reaction chambers, such as those reaction chambers disclosed herein. One or more of the steps shown in FIG. 7 may be rearranged, omitted, and/or otherwise modified, and/or other steps added without departing from the scope of the disclosure.

Method 700 may begin with step 702, which may involve measuring a plurality of resistances of a heat lamp within a reactor system, such as reactor systems 200 or 300. In an example, the controller 102 is configured and/or programmed to include or measure the known amount of electrical power that is directed to each heat lamp and to determine, from the known amount of electrical power and the measured electrical current flow of the heat lamp (provided by each sensor), a resistance of each individual heat lamp 120. In an example, the controller 102 is programmed to determine the resistance of each individual heat lamp by using the mathematical equation P=I²R, where “P” equals the electrical power (Watts), “I” equals the electrical current (Amps), and “R” is the resistance (Ohms). The power can be the power provided to a heat lamp to obtain a desired temperature as measured and controlled using one or more pyrometers, 208, 210, 308 and 310. Configured in this manner, the controller 102 is programmed to determine the resistance associated with each individual heat lamp. In an example, resistance values may be stored in a memory 112 of the controller 102 or otherwise logged. In an example, the controller 102 can base the measured resistances off of either a reduced pressure baseline power or an atmosphere pressure baseline power based on which reactor system is being used.

The resistance can be measured at the beginning or end of each process and/or can be measured at periodic intervals and/or before and/or after a process. In an example, for purposes of determining resistance values of each heat lamp at a known or consistent operating or heating state during the semiconductor fabrication process (i.e., for purposes of consistency), the controller 102 is programmed by a user or the like to determine the heat lamp resistance at the same or similar determined operating or heating state during each subsequent semiconductor fabrication process. The particular state of operation that is determined for such heat lamp resistance determination may vary depending on a number of factors such as the user's preferences associated with the semiconductor fabrication process (e.g., preferences associated with a throughput of one of more substrates, or the like), the particular type of semiconductor fabrication process and the different operating states of the same, and/or the type(s) of heat lamps or other lamps to be measured that are used.

It can be advantageous to measure the plurality of resistances when the reactor is not too busy, such as during a cleaning or etching of the reactor, e.g., after a deposition process. In an example, depending on the particular names given to the different operating cycles, the desired consistent operating cycle for heat lamp resistance determination may be during what may be referred to as a “pre-idle recipe.” While the particular operating cycle selected for determining heat lamp resistance may vary, it is to be understood that a feature of such cycle that is selected is that it is the same for each subsequent heat lamp resistance determination for purposes of providing a consistent heat lamp use condition each time so that each subsequent heat lamp resistance determination occurs under the same use conditions.

During step 702, a constant predetermined power can be supplied to each lamp. An average, mean or median resistance for each lamp can be measured and calculated e.g., using sensors such as sensors 502. In an example, the plurality of resistances are measured after an etching process and before a pre-coating process of the semiconductor fabrication process.

At step 704, the controller may perform N comparisons of a prior resistance to a current resistance. In an example, N may refer to a real number, which may be customized by a user and stored at the memory 112 of the controller 102 and is further described below.

At step 706, the controller 102 may determine whether a difference between each N comparison of the prior resistance and the current resistances exceeds a threshold. If the difference exceeds the threshold, then the method 700 may proceed to step 708. If the difference does not exceed the threshold, then the method 700 may proceed back to step 702.

In an example, the threshold is determined and entered, stored, or otherwise logged for controller access (e.g., entered via user interface 108 and stored within memory 112). The threshold may vary depending on such factors as the particular type of heat lamp that is being used and/or the particular location of the heat lamp relative to the reactor. In an example, the threshold may be configured based on user preferences, depending on how conservative or aggressive the user wishes to be with respect to determining when to trigger the abort process. A user may wish to be more conservative with respect to triggering the abort process in order to err on the side of replacing the heat lamp sooner, as opposed to being more aggressive with respect to triggering the abort process, in order to err on the side of maximizing the lifespan/use of the heat lamp. In an example, the threshold is 0.5 Ohms, representing a more conservative threshold. In another example, the threshold is 1 Ohm, representing a more aggressive threshold. In another example, the threshold is between 0.5 Ohms and 2 Ohms. Different thresholds (e.g., a threshold between 0.5 Ohms and 1.5 Ohms, a threshold between 0.5 Ohms to 1 Ohm, etc.) may be configured without departing from the scope of the disclosure.

At step 708, the controller 102 may trigger the abort process based on the difference between each of the N consecutive comparisons of the prior resistance and the current resistance exceeding the threshold. This may indicate, for example, that the heat lamp has approached an inefficient operating state that is near or nearing an end of effective service life of the heat lamp.

In an example, the N value is determined and entered, stored, or otherwise logged for controller access (e.g., entered via user interface 108 and stored within memory 112). In an example, for N=2, two consecutive comparisons are made, in which case the method 700 may be similar to the method 600 described with reference to FIG. 6. The N value may be configured based on user preferences, which may depend on how conservative or aggressive the user wishes to be with respect to determining when to trigger the abort process (similar to configuring the threshold described at step 706). In an example, having N=2 represents a more conservative way of determining when to trigger the abort process. In another example, having N=5 represents a more aggressive way of determining when to trigger the abort process.

At step 710, the controller 102 may suspend the semiconductor fabrication process by generating one or more instructions stored at, for example, memory 112, and executed by processor 104. In this manner, the controller 102 may, advantageously, prevent the continuation of the semiconductor fabrication process using a potentially defective heat lamp, which may cause poor quality associated with the production of the substrate.

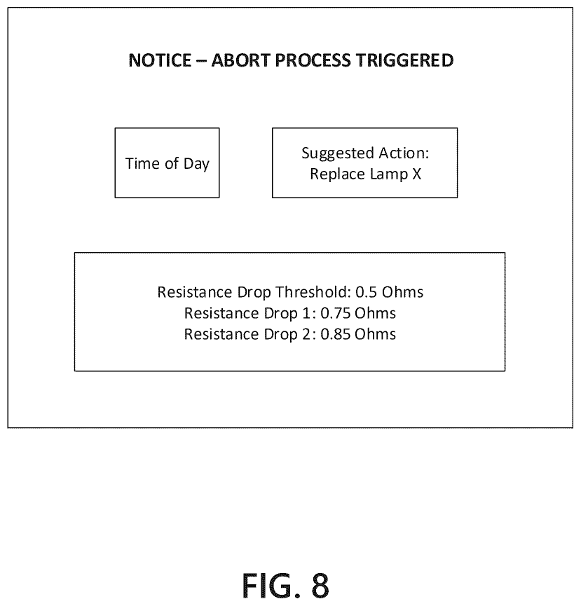

With additional reference to FIG. 8, an exemplary graphical user interface (GUI) is illustrated. In an example, the GUI may be displayed or output (using e.g., user interface 108 and controlled by the controller 102) based on the abort process being triggered by the controller 102 (e.g., displayed as part of the actions performed at step 612 or step 708). In an example, the GUI may be configured to display information such as a time of day in which the abort process was triggered, an indication of a heat lamp that needs to be replaced, a resistance drop threshold (e.g., the threshold described at steps 608-610 or step 706), one or more resistance drops that triggered the abort process, and/or other similar information.

Although but a few example systems and methods for determining when to trigger an abort process during semiconductor fabrication processing have been disclosed in detail above, those skilled in the art will readily appreciate that many modifications are possible in the example embodiments without materially departing from the intent and purpose of the example systems and method as disclosed herein. For example, as noted above, systems and methods as disclosed herein may be used to monitor the health or condition of not only heat lamps but other lamps used during semiconductor fabrication processing. Also, while the systems and methods described particular methods or approaches for providing a visual or audible indication to a user of when it was determined that the abort process was triggered, systems and methods as disclosed herein may be configured to provide such indications by other techniques such as by using wireless or cellular communication devices or the like to provide a text message alert or other type of signal to a user. Accordingly, all such modifications of systems and methods for determining when to trigger an abort process during semiconductor fabrication processing are intended to be included within the scope of this disclosure as defined in the following claims.

What is claimed is:

1. A system comprising:
a reaction chamber comprising a susceptor disposed within the reaction chamber;
a heat lamp disposed outside the reaction chamber and optically coupled to the susceptor by a wall of the reaction chamber; and
a controller for determining when to trigger an abort process during a semiconductor fabrication process, wherein the controller is configured to:
measure a plurality of resistances of the heat lamp during a time period;
compare a first resistance of the measured plurality of resistances to a second resistance of the measured plurality of resistances to determine whether a difference between the first resistance and the second resistance exceeds a threshold, and wherein the first resistance is measured prior to the second resistance;
compare the second resistance to a third resistance of the measured plurality of resistances to determine whether a difference between the second resistance and the third resistance exceeds the threshold, and wherein the second resistance is measured prior to the third resistance;
trigger the abort process based on:
the difference between the first resistance and the second resistance exceeding the threshold; and
the difference between the second resistance and the third resistance exceeding the threshold; and
based on triggering the abort process, generate one or more instructions to suspend the semiconductor fabrication process.

2. The system of claim 1, wherein the threshold is between 0.5 Ohms and 2 Ohms.

3. The system of claim 1, wherein the measuring the plurality of resistances is performed after an etching process and before a pre-coating process of the semiconductor fabrication process.

4. The system of claim 1, wherein the controller is further configured to:
control a user interface, based on the abort process being triggered, to display an indication that the abort process was triggered.

5. The system of claim 1, wherein the system further comprises a plurality of heat lamps disposed outside of the reaction chamber and optically coupled to the susceptor by the wall of the reaction chamber, and wherein the controller is further configured to determine when to trigger the abort process for each heat lamp of the plurality of heat lamps.

6. The system of claim 1, further comprising:
a sensor that determines an electrical current of the heat lamp, and wherein the controller measures the plurality of resistances from the electrical current of the heat lamp as determined by the sensor and an amount of electrical power used to power the heat lamp.

7. The system of claim 6, wherein the amount of electrical power is determined using one or more pyrometers.

8. A system comprising:
a reaction chamber comprising a susceptor disposed within the reaction chamber;
a heat lamp disposed outside the reaction chamber and optically coupled to the susceptor by a wall of the reaction chamber; and
a controller for determining when to trigger an abort process during a semiconductor fabrication process, wherein the controller is configured to:
measure a plurality of resistances of the heat lamp during a time period;
perform N consecutive comparisons of a prior resistance of the measured plurality of resistances to a current resistance of the measured plurality of resistances, to determine whether a difference between each comparison of the prior resistance and the current resistance exceeds a threshold;
trigger the abort process based on the difference between each of the N consecutive comparisons of the prior resistance and the current resistance exceeding the threshold; and
based on triggering the abort process, generate one or more instructions to suspend the semiconductor fabrication process.

9. The system of claim 8, wherein the threshold is between 0.5 Ohms and 2 Ohms.

10. The system of claim 8, wherein the measuring the plurality of resistances is performed after an etching process and before a pre-coating process of the semiconductor fabrication process.

11. The system of claim 8, wherein the controller is further configured to:
control a user interface, based on the abort process being triggered, to display an indication that the abort process was triggered.

12. The system of claim 8, wherein the system further comprises a plurality of heat lamps disposed outside of the reaction chamber and optically coupled to the susceptor by the wall of the reaction chamber, and wherein the controller is further configured to determine when to trigger the abort process for each heat lamp of the plurality of heat lamps.

13. The system of claim 8, further comprising:
a sensor that determines an electrical current of the heat lamp, and wherein the controller measures the plurality of resistances from the electrical current of the heat lamp as determined by the sensor and an amount of electrical power used to power the heat lamp.

14. The system of claim 13, wherein the amount of electrical power is controlled using one or more pyrometers.

15. A controller for determining when to trigger an abort process during a semiconductor fabrication process, comprising:
one or more processors; and
memory storing computer-executable instructions, that when executed by the one or more processors, cause the controller to, at a reaction chamber comprising a susceptor disposed within the reaction chamber and a heat lamp disposed outside the reaction chamber and optically coupled to the susceptor by a wall of the reaction chamber:
measure a plurality of resistances of the heat lamp during a time period;
compare a first resistance of the measured plurality of resistances to a second resistance of the measured plurality of resistances to determine whether a difference between the first resistance and the second resistance exceeds a threshold, and wherein the first resistance is measured prior to the second resistance;
compare the second resistance to a third resistance of the measured plurality of resistances to determine whether a difference between the second resistance and the third resistance exceeds the threshold, and wherein the second resistance is measured prior to the third resistance;
trigger the abort process based on:
the difference between the first resistance and the second resistance exceeding the threshold; and
the difference between the second resistance and the third resistance exceeding the threshold; and
based on triggering the abort process, generate one or more instructions to suspend the semiconductor fabrication process.

16. The controller of claim 15, wherein the threshold is between 0.5 Ohms and 2 Ohms.

17. The controller of claim 15, wherein the measuring the plurality of resistances is performed after an etching process and before a pre-coating process of the semiconductor fabrication process.

18. The controller of claim 15, wherein the memory storing computer-executable instructions, that when executed by the one or more processors, further cause the controller to:
control a user interface, based on the abort process being triggered, to display an indication that the abort process was triggered.

19. The controller of claim 15, further comprising a plurality of heat lamps disposed outside of the reaction chamber and optically coupled to the susceptor by the wall of the reaction chamber, and wherein the memory storing computer-executable instructions, that when executed by the one or more processors, further cause the controller to:
determine when to trigger the abort process for each heat lamp of the plurality of heat lamps.

20. The controller of claim 15, further comprising a sensor that determines an electrical current of the heat lamp, and wherein the controller measures the plurality of resistances from the electrical current of the heat lamp as determined by the sensor and an amount of electrical power used to power the heat lamp.
